(19) United States
(12) Patent Application Publication
(10) Pub. No.: US 2026/0016536 A1
(43) Pub. Date: Jan. 15, 2026

(54) SIGNAL TESTING

(71) Applicant: Micron Technology, Inc., Boise, ID (US)

(72) Inventors: Maria Pat F. Chavarria, Boise, ID (US); Chanz T. Murata, Boise, ID (US); Dong Uk Lee, Boise, ID (US); Sangjin Byeon, Boise, ID (US); Rosa M. Avila-Hernandez, Boise, ID (US); Shadden Kerstetter, Kuna, ID (US); Ali Brooks-Fritel, Eagle, ID (US); Ivana Gigante, Boise, ID (US)

(21) Appl. No.: 19/258,058

(22) Filed: Jul. 2, 2025

Related U.S. Application Data
(60) Provisional application No. 63/669,615, filed on Jul. 10, 2024.

(51) Int. Cl. G01R 31/3193; G01R 31/30; G01R 31/319

(52) U.S. Cl. CPC G01R 31/3193; G01R 31/3012; G01R 31/31905

(57) ABSTRACT

Apparatuses and methods can be related to testing signals. An apparatus can be located on a memory die having a probe-based interface. The apparatus can include an input buffer located on the apparatus and configured to receive an input signal, a latch signal, and a buffer reference voltage, characterize the input signal based on the latch signal and the buffer reference voltage, and provide output data comprising a digital reconstruction of the input signal to an output driver located on the memory die.

### PRIORITY INFORMATION

This application claims the benefits of U.S. Provisional Application No. 63/669,615, filed on Jul. 10, 2024, the contents of which are incorporated herein by reference.

### TECHNICAL FIELD

The present disclosure relates generally to memory, and more particularly to apparatuses and methods associated with signal testing.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications, including, but not limited to personal computers, portable memory sticks, digital cameras, cellular telephones, portable music players such as MP3 players, movie players, and other electronic devices. Memory cells can be arranged into arrays, with the arrays being used in memory devices.

Devices, such as electronic devices used during computing operations, can be tested to determine whether the devices emit signals that may interfere with other devices. Devices can emit electromagnetic signals and/or radio frequency signals. Devices can be designed so the electromagnetic signals and/or radio frequency signals are at a level that does not interfere with the operation of other devices.

Test equipment can be used to measure signals emitted from devices under test. Test equipment can include computing equipment and circuitry to operate a device under test (DUT) and measure electromagnetic signals and/or radio frequency signals emitted by a DUT.

### BRIEF DESCRIPTION OF THE DRAWINGS

FIG. 1 is a block diagram of an apparatus in the form of a computing system including a memory device in accordance with a number of embodiments of the present disclosure.

FIG. 2 illustrates a block diagram of an apparatus in the form of a testing system in accordance with a number of embodiments of the present disclosure.

FIG. 3 illustrates a two-dimensional plot of an input signal in accordance with a number of embodiments of the present disclosure.

FIG. 4 illustrates an example flow diagram of a method for testing a signal in accordance with a number of embodiments of the present disclosure.

FIG. 5 illustrates an example machine of a computer system within which a set of instructions, for causing the machine to perform various methodologies discussed herein, can be executed.

### DETAILED DESCRIPTION

The present disclosure includes apparatuses and methods related to testing signals. In various examples, the accuracy of probe-based interface testing and characterization can be improved by measuring a signal at the probe-based interface. For instance, high bandwidth memory (HBM) interface characterization can be improved.

HBM is a type of memory that uses probes for testing. While HBM is discussed herein, other memory types may be used in examples of the present disclosure. HBM can include the stacking of memory dies (e.g., DRAM memory dies), and the stack may be connected to a memory controller or stacked on a processor. The vertically stacked memory can be interconnected by metal interconnects known as through silicon vias (TSV). For instance, memory devices can be an HBM stack that is coupled to a substrate of a memory system without utilizing a memory module. The memory system can include mounts that can be HBM mounts. The memory devices can be mounted via mounts around a processor.

HBM can be sold as bare cubes, in contrast to other DRAM products that are typically sold in packages. As noted, HBM (among other memory types) uses microbumps instead of solder balls that packaged products use, and the small pitch of the microbump array necessitates probe-based testing. Validation of a microbump interface for HBM can be important because it is not tested in manufacturing.

In some approaches, HBM interface characterization includes a tester signal that is degraded by an unknown amount before reaching the HBM interface. This can add error to measurements, which can increase a difficulty of identifying issues that could affect customers.

Other approaches include signal characterization using a loopback DUT. In such approaches, a degraded signal at the DUT is routed through a separate path back to the tester which can introduce additional degradation. The degradation from the input and the output paths may not be equal, which can prevent quantification of the degradation of either the input or the output path.

Yet other approaches utilize an oscilloscope to measure a signal at the DUT. An oscilloscope, however, cannot be used to characterize signals at probe tips, which may be necessary for product validation (e.g., using a tester interface board/probe card) to create an electrical connection between the tester and the microbumps. Probe tips are fragile and may be damaged if connected to an oscilloscope.

In contrast, examples of the present disclosure can include measuring the signal at the probe-based (e.g., HBM) interface, which can improve characterization accuracy and help differentiate between device (e.g., HBM) and tester/interface board issues. An on-die circuit can be used to help characterize input signals from the tester at the microbumps. The tester can be used to characterize signal integrity of the probe-based interface. Additional circuitry can be excluded from other DUT input pins to improve accuracy, in some examples, and having the on-die circuit separate from normal DUT operations can reduce internal noise that affects accuracy (e.g., internal noise can reduce accuracy). Examples of the present disclosure can allow for probe-based testing for DUTs with microbumps, or DUTs that cannot be directly touched or tested directly (e.g., due to their particular interface-type).

In some examples of the present disclosure, an apparatus designed for a DUT can be located on a memory die having a probe-based interface. The apparatus can include an input buffer located on the apparatus and configured to receive an input signal, a latch signal, and a buffer reference voltage, characterize the input signal based on the latch signal and the buffer reference voltage, and provide output data comprising a digital reconstruction of the input signal to an output driver located on the memory die.

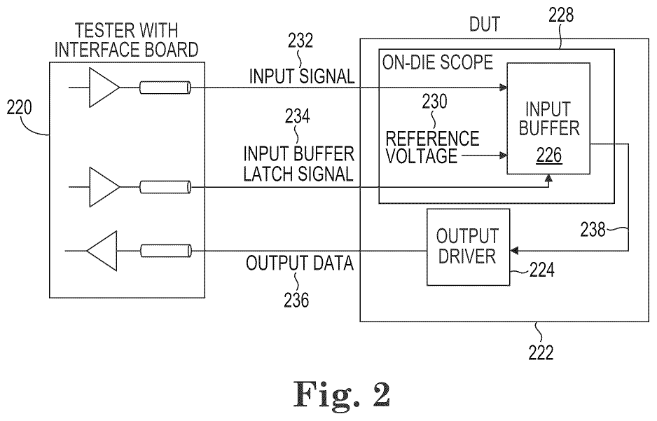

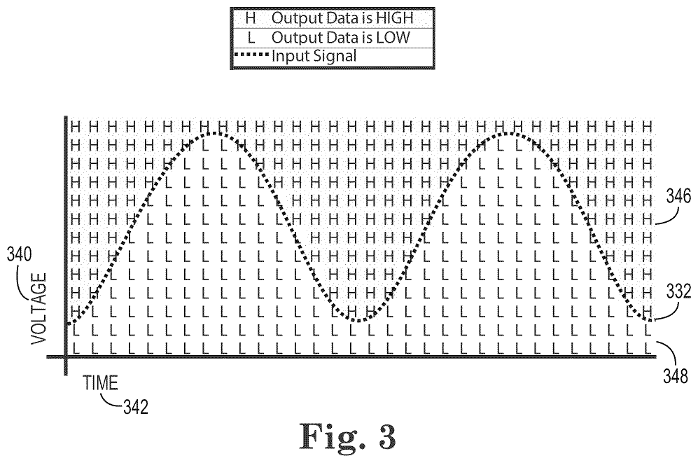

The figures herein follow a numbering convention in which the first digit or digits correspond to the drawing figure number and the remaining digits identify an element or component in the drawing. Similar elements or components between different figures may be identified by the use of similar digits. For example, 232 may reference element “32” in FIG. 2, and a similar element may be referenced as 332 in FIG. 3. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

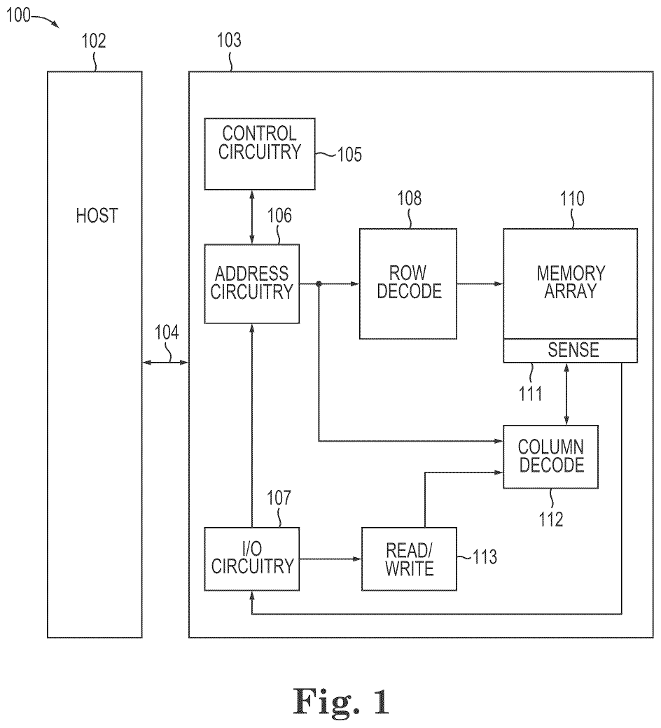

FIG. 1 is a block diagram of an apparatus in the form of a computing system 100 including a memory device 103 in accordance with a number of embodiments of the present disclosure. As used herein, a memory device 103, memory array 110, and/or a host 102, for example, might also be separately considered an “apparatus.”

In various examples, the computing system 100 includes a host 102 coupled to memory device 103 via an interface 104. The memory device 103 can be coupled to a memory module which is coupled to the computing system 100 via the interface 104. The computing system 100 can be a personal laptop computer, a desktop computer, a digital camera, a mobile telephone, a memory card reader, or an Internet-of-Things (IoT) enabled device, among various other types of systems. The host 102 can include a number of processing resources (e.g., one or more processors, microprocessors, or some other type of controlling circuitry) capable of accessing the memory device 103. The computing system 100 can include separate integrated circuits, or both the host 102 and the memory device 103 can be on the same integrated circuit. For example, the host 102 may be a system controller of a memory system comprising multiple memory devices 103, with the system controller providing access to the respective memory devices 103 by another processing resource such as a central processing unit (CPU).

In the example shown in FIG. 1, the host 102 is responsible for executing an operating system (OS) and/or various applications that can be loaded thereto (e.g., from memory device 103 via control circuitry 105). The OS and/or various applications can be loaded from the memory device 103 by providing access commands from the host 102 to the memory device 103 to access the data comprising the OS and/or the various applications. The host 102 can also access data utilized by the OS and/or various applications by providing access commands to the memory device 103 to retrieve said data utilized in the execution of the OS and/or the various applications.

For clarity, the computing system 100 has been simplified to focus on features with particular relevance to the present disclosure. The memory array 110 can be a DRAM array, SRAM array, STT RAM array, PCRAM array, TRAM array, RRAM array, NAND flash array, NOR flash array, and/or 3D Cross-point array for instance. The memory array 110 can comprise memory cells arranged in rows coupled by access lines (which may be referred to herein as word lines or select lines) and columns coupled by sense lines (which may be referred to herein as digit lines or data lines). Although the memory array 110 is shown as a single memory array, the memory array 110 can represent a plurality of memory arrays arraigned in banks of the memory device 103.

The memory device 103 includes address circuitry 106 to latch address signals provided over an interface 104. The interface can include, for example, a physical interface (e.g., a data bus, an address bus, and a command bus, or a combined data/address/command bus) employing a suitable protocol. The physical interface can also include a memory slot to which a memory module comprising the memory device 103 is coupled. The physical interface can also include an array area to which the memory device 103 is directly coupled. Such protocol may be custom or proprietary, or the interface 104 may employ a standardized protocol, such as Peripheral Component Interconnect Express (PCIe), Gen-Z interconnect, cache coherent interconnect for accelerators (CCIX), or the like. Address signals are received and decoded by a row decoder 108 and a column decoder 112 to access the memory arrays 110. Data can be read from memory arrays 110 by sensing voltage and/or current changes on the sense lines using sensing circuitry 111. The sensing circuitry 111 can be coupled to the memory arrays 110. Each memory array and corresponding sensing circuitry can constitute a bank of the memory device 103. The sensing circuitry 111 can comprise, for example, sense amplifiers that can read and latch a page (e.g., row) of data from the memory array 110. The I/O circuitry 107 can be used for bi-directional data communication with the host 102 over the interface 104. The read/write circuitry 113 is used to write data to the memory arrays 110 or read data from the memory arrays 110. As an example, the read/write circuitry 113 can comprise various drivers, latch circuitry, etc.

Control circuitry 105 decodes signals provided by the host 102. The signals can be commands provided by the host 102. These signals can include chip enable signals, write enable signals, and address latch signals that are used to control operations performed on the memory array 110, including data read operations, data write operations, and data erase operations. In various embodiments, the control circuitry 105 is responsible for executing instructions from the host 102. The control circuitry 105 can comprise a state machine, a sequencer, and/or some other type of control circuitry, which may be implemented in the form of hardware, firmware, or software, or any combination of the three. In some examples, the host 102 can be a controller external to the memory device 103. For example, the host 102 can be a memory controller which is coupled to a processing resource of a computing device. Data can be provided to the memory array 110 and/or from the memory array via the data lines coupling the memory array 110 to the I/O circuitry 107.

In various instances, the memory device 103 can be utilized to store testing and validation results of a microbump interface, signal measurements at an HBM interface (or other interface) and/or characterization of an HBM interface (or other interface). The host 102 can be configured to access the stored data to validate a microbump interface, for example.

FIG. 2 illustrates a block diagram of an apparatus in the form of a testing system in accordance with a number of embodiments of the present disclosure. The testing system, referred to herein as system, can include various components. The components can include a tester 220 (e.g., a probe testing device), a DUT 222 (e.g., an HBM), an on-die scope 228 (e.g., on-die circuit) located on the DUT 222 including an input buffer 226, and an output driver 224 located on the DUT 222, among other components that can be implemented in the testing system.

The tester 220 can transmit an input signal 232 that degrades through an interface board between the tester 220 and the DUT 222. A separate input buffer 226, included on the DUT 222, can capture the degraded input signal 232. A binary result 238 from the input buffer 226 can be transported back to the tester 220 via an output driver 224 on the DUT 222 as output data 236. In some examples, a digital reconstruction of the degraded input signal 232 can be created by varying the input buffer 226 reference voltage 230 and the input buffer latch signal 234.

Put another way, the on-die scope 228 can be an apparatus located on a memory die (e.g., HBM, microbump array, bare cube memory die, etc.) having a probe-based interface. The on-die scope can include the input buffer 226 that receives the input signal 232, the latch signal 234, and the reference voltage 230. The input signal 232 can be characterized based on the latch signal 234 and the reference voltage 230. The input buffer 226 can then provide output data 236 comprising a digital reconstruction of the input signal 232 to an output driver 224 located on the memory die.

The testing system can allow for characterization of the input signal 232 at the DUT 222, which can improve reconstruction of the input signal 232 as it degrades through the DUT 222. The reconstruction of the degraded input signal 232 can be used to determine with greater accuracy the functionality of the DUT 222, in contrast to other approaches, which do not allow for characterization or reconstruction of a signal at the DUT.

FIG. 3 illustrates a two-dimensional plot of an input signal 332 in accordance with a number of embodiments of the present disclosure. The plot displays the input signal 332 with respect to time 342 (e.g., latch time) and voltage 340 (e.g., reference voltage). The input buffer reference voltage (e.g., voltage 340) and the input buffer latch time (e.g., time 342) can be adjusted to create the plot. For instance, when the time 342 and/or the voltage 340 are adjusted, the output data from the on-die scope may be higher 346 or lower 348 with respect to a reference voltage. This data can allow for reconstruction of the input signal 332 after degradation.

The reconstructed input signal 332 can be compared to the original input signal which is coming from the tester (e.g., tester 220) to determine if signal degradation has occurred. For instance, the amount of signal degradation may be coming from the tester and the interface board. Determining an amount of degradation can aid in decisions regarding the functionality of the DUT. For instance, the characterization results can be adjusted if the reconstructed signal is significantly (e.g., above a threshold) different than the original input signal 332.

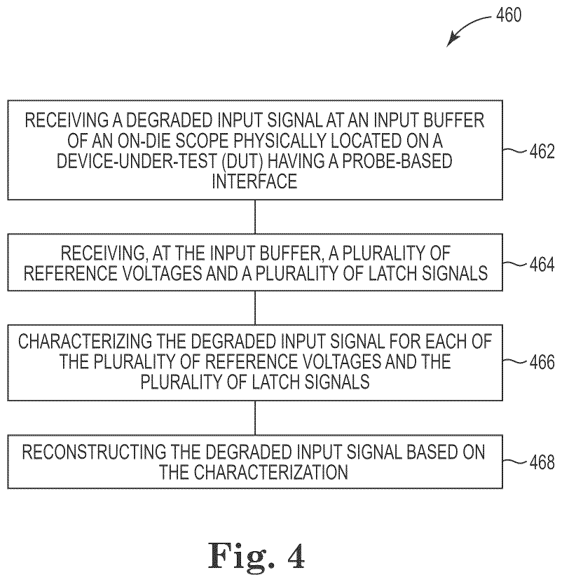

FIG. 4 illustrates an example flow diagram of a method 460 for testing a signal in accordance with a number of embodiments of the present disclosure. The method 460 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 460 is performed by the control circuitry (e.g., controller) 105 and/or by the host 102 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At box 462, the method 460 can include receiving a degraded input signal at an input buffer of an on-die scope physically located on a DUT having a probe-based interface. For example, the DUT may be an HBM or other device having a probe-based interface. At box 464, the method 460 can include receiving, at the input buffer, a plurality of reference voltages and a plurality of latch signals. The input buffer can allow for signals to be detected right at the microbumps of the DUT instead of an interface board, which allows for detection as the signal is received at the input buffer.

The method 460, at box 466, can include characterizing the degraded input signal for each of the plurality of reference voltages and the plurality of latch signals. In some examples, the degraded input signal can be characterized without contacting microbumps of the probe-based interface. Examples described herein, for instance in contrast to using simply an HBM interface, can allow for accurately characterizing what the signal looks like as it is received. Other approaches may skew the signal and the characterization may not be as accurate.

At box 468, the method 460 can include reconstructing the degraded input signal based on the characterization. For example, the degraded input signal can be reconstructed at the microbumps of the probe-based interface. The reconstruction can be created by varying the input buffer reference voltage received and latch time/signal received. The reconstruction, in some instances, can include constructing a two-dimensional plot of the degraded input signal, for instance as illustrated in FIG. 3. The reconstruction, for example, can be a recreation of what the on-die scope sees as the degraded input signal.

In some examples, the method 460 can include comparing the reconstructed degraded input signal to a known input signal determining a degradation value of the degraded input signal based on the comparison. If the degraded input signal is different (e.g., based on a particular threshold standard), it can be determined how much an input signal is degraded by the interface board (e.g., interface board 220), if the DUT is working as desired, if changes need to be made to the DUT, or if the DUT should be discarded, among other determinations.

Examples of the present disclosure can allow for visualization of the input signal at the input buffer, which can allow for functional determinations regarding the DUT, in contrast to other approaches which do not allow for visualization of signals at the DUT. Put another way, capturing signals at the DUT can improve accuracy of device interface characteristics. For instance, certain datasheet specification, such as input setup and hold times, may be affected by a slew rate of the input signal. Probe interface boards can also be evaluated, in some examples, because of the ability to measure signals at the DUT.

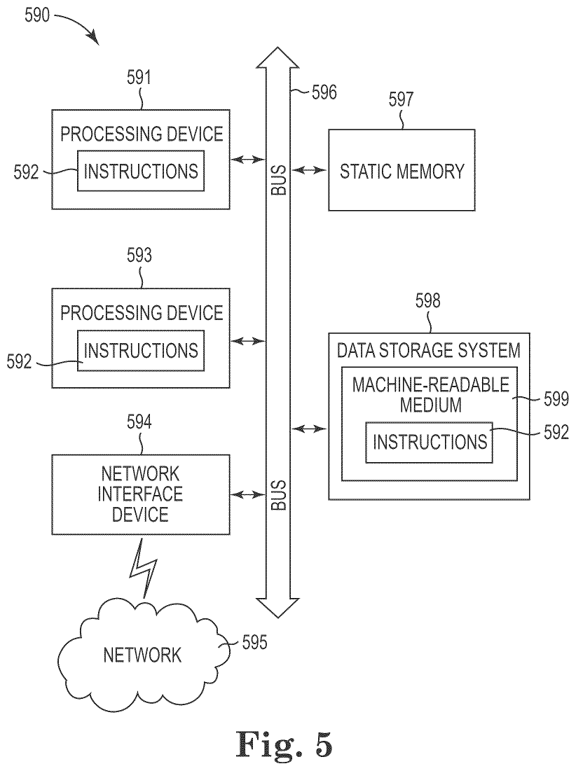

FIG. 5 illustrates an example machine of a computer system 590 within which a set of instructions, for causing the machine to perform various methodologies discussed herein, can be executed. In various embodiments, the computer system 590 can correspond to a system (e.g., the computing system 100 of FIG. 1) that includes, is coupled to, or utilizes a memory sub-system (e.g., the memory device 103 of FIG. 1) or can be used to perform the operations of a controller (e.g., the controller circuitry 105 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

Processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media.

In one embodiment, the instructions 592 include instructions to implement functionality corresponding to the host 102 and/or the memory device 103 of FIG. 1. While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

As used herein, “a number of” something can refer to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus located on a memory die having a probe-based interface, comprising:
an input buffer located on the apparatus and configured to:
receive an input signal, a latch signal, and a buffer reference voltage;
characterize the input signal based on the latch signal and the buffer reference voltage; and
provide output data comprising a digital reconstruction of the input signal to an output driver located on the memory die.

2. The apparatus of claim 1, wherein the apparatus is a circuit.

3. The apparatus of claim 1, wherein the apparatus is a scope.

4. The apparatus of claim 1, wherein the memory die is a high bandwidth memory die.

5. The apparatus of claim 1, wherein the memory die comprises a microbump array.

6. The apparatus of claim 1, wherein the input signal is degraded through an interface board between a tester and a device under test.

7. The apparatus of claim 1, wherein the memory die is a device under test, and the input signal is received from a tester.

8. The apparatus of claim 7, wherein the tester is a probe testing device.

9. The apparatus of claim 1, wherein the output driver is configured to provide the digital reconstruction to the tester.

10. A system, comprising:
a device under test (DUT) having a probe-based interface; and
an on-die circuit located on the DUT to characterize input signals from a tester at microbumps of the die.

11. The system of claim 10, wherein the DUT is a high bandwidth memory die.

12. The system of claim 10, wherein the DUT is a bare cube memory die.

13. The system of claim 10, wherein the input signals are degraded input signals that are degraded through an interface board between the tester and the DUT.

14. The system of claim 10, wherein the on-die circuit is configured to characterize the input signals with respect to voltage and time.

15. The system of claim 10, further comprising a reconstruction of the input signals based on the characterization of the input signals.

16. A method, comprising:
receiving a degraded input signal at an input buffer of an on-die scope physically located on a device-under-test (DUT) having a probe-based interface;
receiving, at the input buffer, a plurality of reference voltages and a plurality of latch signals;
characterizing the degraded input signal for each of the plurality of reference voltages and the plurality of latch signals; and
reconstructing the degraded input signal based on the characterization.

17. The method of claim 16, comprising reconstructing the degraded input signal at the microbumps of the probe-based interface.

18. The method of claim 16, comprising:
comparing the reconstructed degraded input signal to a known input signal; and
determining a degradation value of the degraded input signal based on the comparison.

19. The method of claim 16, comprising characterizing the degraded input signal with respect to voltage and time.

20. The method of claim 16, wherein reconstructing the degraded input signal comprises constructing a two-dimensional plot of the degraded input signal.
